(19) United States
(12) Patent Application Publication
(10) Pub. No.: US 2015/0075418 A1
(43) Pub. Date: Mar. 19, 2015

(54) CRUCIBLES MADE WITH THE COLD FORM PROCESS

(71) Applicant: ATI PROPERTIES, INC., Albany, OR (US)

(72) Inventor: Matthew V. Fonte, Concord, MA (US)

(21) Appl. No.: 14/551,545

(22) Filed: Nov. 24, 2014

Related U.S. Application Data
(63) Continuation of application No. 14/186,249, filed on Feb. 21, 2014.
Application No. 14/186,249 is a continuation of application No. 13/372,287, filed on Feb. 13, 2012, now abandoned.
(60) Provisional application No. 61/441,994, filed on Feb. 11, 2011.

(51) Int. Cl. C30B 15/10; C23C 8/04; C23C 8/20; C30B 29/20

(52) U.S. Cl. CPC C30B 15/10; C30B 29/20; C23C 8/04; C23C 8/20
USPC 117/13; 117/208; 148/237; 72/364

(57) ABSTRACT

A crucible for growing crystals, the crucible being formed from Molybdenum and Rhenium. A crucible for growing crystals, the crucible being formed from a metal selected from Group V of the Periodic Table of the Elements. A crucible for growing crystals, the crucible comprising a body and a layer formed on at least a portion of the body, the layer being formed out of Molybdenum.

### REFERENCE TO PRIOR PATENT APPLICATIONS

This patent application is a continuation application claiming priority under 35 U.S.C. §120 to co-pending U.S. application Ser. No. 14/186,249, filed on Feb. 21, 2014, which is a continuation of U.S. application Ser. No. 13/372,287, filed on Feb. 13, 2012, which in turn claims the benefit of U.S. Provisional Patent Application No. 61/441,994, filed on Feb. 11, 2011, which patent application is hereby incorporated herein by reference.

### FIELD OF THE INVENTION

This invention relates to crucibles in general, and more particularly to crucibles for growing crystals.

### BACKGROUND OF THE INVENTION

Light emitting diodes (LEDs) are ubiquitous in modern society: they are in traffic lights, automobile interiors, backlights in cell phones, and many other applications. Their growing popularity comes from their many advantages over incandescent and fluorescent lamps including a high energy efficiency, long lifetimes, compact size, and shock resistance. Furthermore, they can emit light of a precise color, which is useful for many applications. Currently, commercial LEDs are available that emit light over the entire visible range—from red to blue, plus infrared light. One of the main problems in creating LEDs is the poor formability and consequently high cost of suitable materials available for crucible fabrication. In addition to finding a crucible material that is chemically inert during the single crystal melting growth process, the material must be thermally stable at 2,100° C. so that the crucible's growth doesn't put crystal under stress as it is cooled from the growth temperature.

### Sapphire Single Crystals:

Crystal growth is a significant step for the semiconductor industry as well as for optical applications and solar industries. Sapphire single crystals are used for high power laser optics, high pressure components and substrates for LEDs. Because of the high temperatures (up to 2,200° C.) and harsh chemical environments occurring in the single crystal growth process, components in the growth chamber must be made from molybdenum or tungsten. The technique of crystal growing is a straightforward process. Al₂O₃ (alumina) is melted in a molybdenum crucible. The melt “wets” the surface of the molybdenum die and moves up by capillary attraction. A sapphire ‘seed crystal’ of desired crystallinity is dipped into the melt on top of the die and ‘pulled’ or drawn out, crystallizing the Al₂O₃ into solid sapphire, in a shape—rod, tube or sheet (ribbon)—determined by the die. Crystal orientation can be tightly controlled—any axis or plane can be produced using proper controls during growth. Uses for die-grown sapphire include:

| | |
|---|---|
| Sapphire fiber | Laser material |
| EFG bulk sapphire uses | Scalpels and ceramic parts |
| Bar code scanners | Military armor |
| Substrates for blue LEDs and laser | Aerospace windows and nose cones |
| diodes | |
| Tubes for plasma applicators | End effector on robotic arm |
| Chamber and viewports | Lift pins |
| End point windows and slits | Thermocouples |

### Molybdenum Crucibles:

A limitation of the production of sapphire single crystals is the difficulty in producing the pure Molybdenum (Mo) crucible. Unlike most all other metals, Molybdenum's mechanical working must be carried out above the ductile-brittle transition temperature, which can be 200° C. (400° F.) to 650° C. (1,200° F.) depending on the geometry of the part being formed and its thickness. Forming processes such as press brake folding of sheet or bending of rod are only possible after localized preheating. Gas flame and/or induction heating are required, ideally to reach red heat for as short a time as possible and only while deformation is taking place. Forming material while it's red hot is difficult due to material smearing/galling, tooling undesirably expanding with heat and tool wear/fatigue failure. There is also the concern of fire when forming metal hot and there are oil based lubricants and hydraulic lines present. Additionally, texture is an important factor during the deep drawing of sheet. Specially produced, cross-rolled sheets (deep-drawing quality) are required. So, the texture of the pre-formed blank needs to be just right or cracks will ensue. The preheating temperature before deep drawing depends on the sheet thickness and the degree of deformation required. Typically several forming passes are required, with intermediate cleaning/annealing, and re-lubrication processes between subsequent forming passes. In short, forming pure Mo is problematic and few companies have had success forming this brittle material.

Crucibles that are in production for growing sapphires can be 17″ diameter×20″ deep with wall thickness ranging from 0.040″ to 0.098″. The length to diameter ratio of this thin crucible can make it challenging to produce, especially in Mo. FIG. 1 is a photo of a seamless, Mo crucible made by Plansee. This Mo crucible could weigh more than 50 lbs. Today the price of Mo is near $330 per lb. The cost in metal alone could be more than $16,000. Then there is the cost to do the fabrication of the difficult-to-form Mo material. The market today could be more than 5,000 Mo crucibles per year. There is a need to find a more practical method of producing the Mo crucibles.

### SUMMARY OF THE INVENTION

In one form of the present invention, there is provided a crucible for growing crystals, the crucible being formed from Molybdenum and Rhenium.

In another form of the present invention, there is provided a crucible for growing crystals, the crucible being formed from a metal selected from Group V of the Periodic Table of the Elements.

In another form of the present invention, there is provided a crucible for growing crystals, the crucible comprising a body and a layer formed on at least a portion of the body, the layer being formed out of Molybdenum.

In another form of the present invention, there is provided a method for forming a crucible for growing crystals, the method comprising the steps of:

preheating a preform blank formed out of molybdenum or a molybdenum alloy; and

flowforming the preform blank into the shape of a crucible, wherein flowforming is performed at a temperature below the recrystallization temperature of the material.

### BRIEF DESCRIPTION OF THE DRAWINGS

These and other objects and features of the present invention will be more fully disclosed or rendered obvious by the following detailed description of the preferred embodiments of the invention, which is to be considered together with the accompanying drawings wherein like numbers refer to like parts, and further wherein:

FIG. 1 is a photograph of a Molybedenum crucible;

FIG. 2 is a graph showing a comparison of the room-temperature tensile elongation of Mo—Re alloys;

FIG. 3 is a graph showing DBTT vs. Re for a variety of materials;

FIG. 4 is a micrograph showing a material which has not been worked significantly during a flowforming process;

FIG. 5 is a micrograph showing a material which has been worked significantly during a flowforming process;

FIG. 6 is a deep draw process, starting from sheet/disc and forming into a bowl with punch and eyes;

FIG. 7 is a cross-sectional view of flowforming a short preform into a long flowformed cylinder;

FIG. 8 is a view showing a spinning process; and

FIG. 9 is a view showing a hydroforming process.

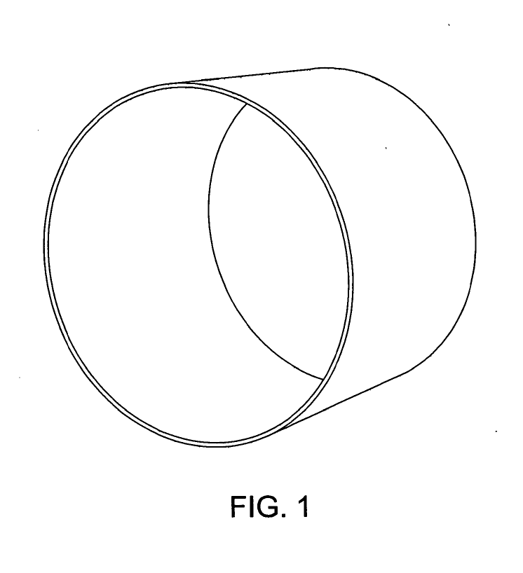

### DESCRIPTION OF THE INVENTION

Molybdenum (Mo) with Rhenium (Re)

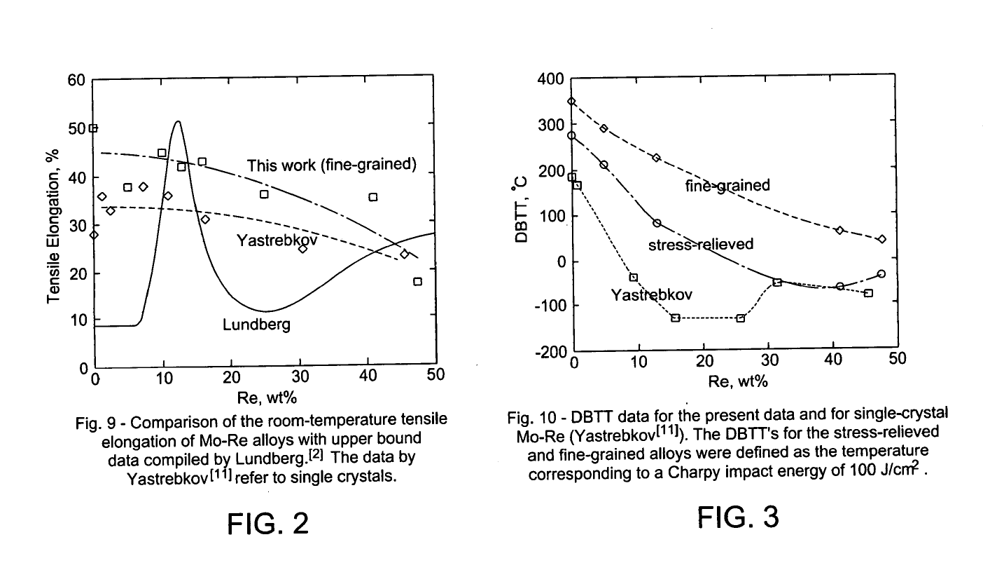

Using Mo with 5%-20% Re increases that the material's ductility and reduces the material's ductile-brittle transition temperature (DBTT) from about 300° C. to about 50° C., making it cold-workable and flowformable at room temperature. The room temp elongation will increase from 8% to 50% (see FIGS. 2-3).

The drawback to adding 5-20% Re is that Re is extremely expensive. So there could be a need to find a less expensive alternative material.

### Tantalum (Ta) and Niobium (Nb) Alloy Crucibles

When alumina melts during the single crystal growth process at temperatures near 2080° C. (3,776° F.), it is not surprising that Mo is used for the crucible because it has a melting temp of 2,470° C. (4,473° F.). Years ago machining small crucibles of Mo was ok but today crucibles are 17″ diameter×19″ deep, and machining solid pieces of Mo is not practical, nor economically/commercially viable. Again, the problem with Mo is that it is not formable with processes like flowforming. Using Tantalum which melts at 3,000° C. (5,425° F.) or Niobium (C-103) which melts at 2,350° C. (4,260° F.) are both better choices for large crucibles because these elements and their alloys are cold formable. Aluminum nitride (AlN) can be melted and left stable at high temperatures in inert atmospheres and melts at 2,800° C. in Ta crucibles. Ta crucibles can also work for Al₂O₃. Ta has a higher melting point compared to ceramics like alumina and boron carbide. Other materials such as Titanium melts at about 1650° C. (3,000° F.) and the melting temperatures of steels are lower, so neither material could work for the temperatures that sapphire single crystals are grown at. Ta and C-103 are very cold-formable and can be flowformed at Dynamic Flowform Corp. Ta and C103 are cheaper than Mo too. These alloys could be deep drawn, spun, flowformed, hydro-formed and a combination of each.

The grain size of the pure molybdenum increased substantially with increasing temperature from 1,700 to 2,300° C. The grain structure of the molybdenum will expand as the temperatures are increased for sapphire crystal growth. However, such grain growth is undesirable in a crucible because it becomes dimensionally unstable. One benefit of flowforming the Ta and Nb is the finer microstructure that will result from the cold work/plastic deformation during flow forming. A fine grain structure will help to keep the crucibles stable during grain growth at high temperatures. In addition to having flowformed grains as small as ASTM 7-14 other additive materials can be blended with the Ta and/or Nb to help keep the fine, flowformed grains from expanding and the crucible undesirably moving during annealing and raising the temperature to 2,050° C. Silicon up to 700 ppm and Thorium up to 500 ppm can be doped into pure Ta to help pin the grains at 2,400° C. (4,352° F.). A flowformed structure will have very fine grains (ASTM 7-14 grain size). Without pinning the grains, the grain growth of Ta at 2,400° C. could cause the grains to grow to ASTM 1-5, causing the crucible to be structurally weaker, more susceptible to embrittlement and dimensionally unstable.

Combining the flowforming with a doped Ta or Nb will create a crucible that has the most uniform, finest grain structure at all temperatures and will keep it the most stable during heating and cooling so not to crack the single crystal. The benefits of silicon and a stable metal oxide addition to Ta and Ta alloys also can be applied to other metals of Group V of the Periodic Table of the Elements, namely Niobium (Columbium) and Vanadium.

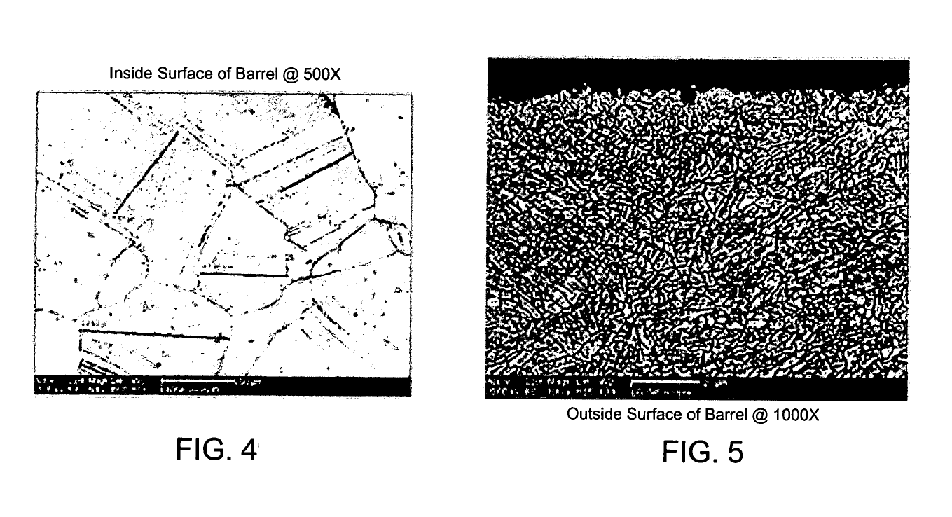

FIG. 4 shows the preform material that hasn't been worked much during flowforming process with large grains, ASTM 4-5. FIG. 5 shows the same material with grains after working. The worked grains are a lot smaller from the flowforming process, ASTM 10-14. Flowforming reduces the grain structure which will help with thermal stability during growing the single crystal and will help to make the crucibles optimized for an even diffusion of Carbon if required.

### Ta and Nb Crucibles Carbonized

A key feature of our technique is the use of tantalum and niobium growth crucibles. Before use, the tantalum crucible, having 1-2 mm thick walls, is annealed at 2,200-2,500° C. in a carbon-containing atmosphere. During the treatment, the crucible weight gradually increases due to the incorporation of C atoms into tantalum and the process is continued until the weight saturates (normally, in 30-40 h). The resulting weight maximum suggests that no free tantalum remains in the crucible. A three-layer structure of Ta/C—Ta—Ta/C kind is initially formed in the crucible walls during this procedure. As the crucible weight is saturating, the central layer gradually disappears due to the interaction of tantalum with carbon that is probably transported from the vapor via diffusion through small pores in the external T/C layers. Exploitation of such pre-carbonized crucibles for PVT growth of bulk AlN showed their remarkable thermal and chemical stability. The totally saturated crucibles can stay for 300-400 hours in the Al/N2 atmosphere at 2300° C. without visible degradation.

Tungsten crucibles are known to be intensively attacked by the reactive Al vapor and rapidly destroyed at high temperatures. Also, both Molybdenum and Tungsten are difficult-to-process materials exhibiting brittle behavior (especially after high temperature annealing). Unlike tungsten and molybdenum, tantalum can be easily processed before the carbonization treatment, which provides good scalability of the technology.

Combining carbon into the anneal of the Ta and Nb alloys at 2,000° C. creates Ta—Si—C and Nb—Si—C, which prevent the crucible from absorbing SiC vapors during the single crystal growth. If we combine flowformed fine grains with Ta doped with Silicon and Thorium to prevent grain growth at crucible temps and diffuse in Carbon to seal off SiC into the tight lattice of the fine grain boundary network, you can have an optimal crucible. Crucibles made in this manner are easy to form, chemically inert, and dimensionally stable with no grain growth. If the Ta or Nb crucibles are so stable they possibly can be used longer or even used multiple times (are reusable). Mo crucibles can be used only one time.

### Composite Crucible:

An alternative method of producing a monolithic Mo, Ta or Nb alloy crucible is to coat the inside of a second crucible with a Mo film, creating a clad or bimetallic crucible. The substrate material can be more formable and less expensive; driving down material and fabrication costs of the composite crucible. Although this technique of coating a crucible with a Mo thin film has never been used before in the application of growing sapphire, single crystals, technically it is achievable. Pure Mo has been deposited to many metallic substrates thru plasma sprayforming, chemical and vapor deposition processes, sputter process, wire arc melting, vacuum plasma spraying, vacuum arc deposition and other thin film deposition processes. Using a thick material as the crucible substrate and coating just a thin film on the inner diameter will use less of the expensive Mo, significantly reducing the part manufacturing cost.

The disadvantage of coating a dissimilar substrate is that the two materials could delaminate or crack apart during the single crystal growth process when the Al₂O₃ (alumina) is melted in the molybdenum crucible at temperatures north of 2,000° C. because of the two materials' different coefficient of thermal expansion rates. Mo has one of the highest melting temperatures of all the elements and its coefficient of thermal expansion (CTE) is the lowest of the engineering metals:

Coefficient of Linear Thermal Expansion (CTE). Approximate
Ranges at Room Temperature to 100° C. (212°
F.), from Lowest to Highest CTE

| CTE | | |
|---|---|---|
| 10⁻⁶/K | 10⁻⁶/° F. | Material |
| 2.6-3.3 | 1.4-1.8 | Pure Silicon (Si) |
| 2.2-6.1 | 1.2-3.4 | Pure Osmium (Os) |
| 4.5-4.6 | 2.5-2.6 | Pure Tungsten (W) |
| 0.6-8.7 | 0.3-4.8 | Iron-cobalt-nickel alloys |
| 4.8-5.1 | 2.7-2.8 | Pure Molybdenum (Mo) |
| 5.6 | 3.1 | Pure Arsenic (As) |
| 6.0 | 3.3 | Pure Germanium (Ge) |
| 6.1 | 3.4 | Pure Hafnium (Hf) |
| 5.7-7.0 | 3.2-3.9 | Pure Zirconium (Zr) |
| 6.3-6.6 | 3.5-3.7 | Pure Cerium (Ce) |
| 6.2-6.7 | 3.4-3.7 | Pure Rhenium (Re) |
| 6.5 | 3.6 | Pure Tantalum (Ta) |
| 4.9-8.2 | 2.7-4.6 | Pure Chromium (Cr) |
| 6.8 | 3.8 | Pure Iridium (Ir) |
| 2.0-12 | 1.1-6.7 | Magnetically soft iron alloys |
| 7.1 | 3.9 | Pure Technetium (Tc) |
| 7.2-7.3 | 4.0-4.1 | Pure Niobium (Nb) |
| 5.1-9.6 | 2.8-5.3 | Pure Ruthenium (Ru) |
| 4.5-11 | 2.5-6.2 | Pure Praseodymium (Pr) |
| 7.1-9.7 | 3.9-5.4 | Beta and near beta titanium |
| 8.3-8.5 | 4.6-4.7 | Pure Rhodium (Rh) |
| 8.3-8.4 | 4.6-4.7 | Pure Vanadium (V) |
| 5.5-11 | 3.1-6.3 | Zirconium alloys |
| 8.4-8.6 | 4.7-4.8 | Pure Titanium (Ti) |
| 8.6-8.7 | 4.8-4.8 | Mischmetal |
| 7.6-9.9 | 4.2-5.5 | Unalloyed or low-alloy titanium |
| 7.7-10 | 4.3-5.7 | Alpha beta titanium |
| 4.0-14 | 2.2-7.8 | Molybdenum alloys |
| 6.8-9.1 | 4.9-5.1 | Pure Platinum (Pt) |
| 7.6-11 | 4.2-5.9 | Alpha and near alpha titanium |
| 9.3-9.6 | 5.2-5.3 | High-chromiun gray cast iron |
| 9.3-9.9 | 5.2-5.5 | Ductile high-chromium cast iron |
| 9.1-10 | 5.1-5.6 | Pure Gadolinium (Gd) |
| 8.4-11 | 4.7-6.3 | Pure Antimony (Sb) |
| 8.6-11 | 4.8-6.3 | Maraging steel |
| 9.9 | 5.5 | Protactinium (Pa) |
| 9.8-10 | 5.4-5.8 | Water-hardening tool steel |
| 10-11 | 5.6-5.9 | Molybdenum high-speed tool steel |
| 6.8-14 | 3.8-7.8 | Niobium alloys |
| 9.3-12 | 5.2-6.5 | Ferritic stainless steel |
| 7.6-14 | 4.2-7.5 | Pure Neodymium (Nd) |
| 11 | 5.9 | Cast ferritic stainless steel |
| 8.9-12 | 4.9-6.9 | Hot work tool steel |
| 9.5-12 | 5.3-6.6 | Martensitic stainless steel |
| 9.9-12 | 5.5-6.5 | Cast martensitic stainless steel |
| 11 | 6.1 | Cermet |
| 10-12 | 5.6-6.6 | Ductile silicon-molybdenum cast iron |
| 10-12 | 5.6-6.5 | Iron carbon alloys |
| 9.3-12 | 5.2-6.9 | Pure Terbium (Tb) |
| 9.8-13 | 5.4-6.9 | Cobalt chromium nickel tungsten |
| 10-12 | 5.8-6.7 | High-carbon high-chromium cold work tool steel |
| 11 | 6.2 | Tungsten high-speed tool steel |
| 8.5-14 | 4.7-7.8 | Commercially pure or low-alloy nickel |
| 11 | 6.3 | Low-alloy special purpose tool steel |
| 7.1-16 | 3.9-8.7 | Pure Dysprosium (Dy) |
| 9.3-13 | 5.2-7.2 | Nickel molybdenum alloy steel |
| 11-12 | 6.1-6.6 | Pure Palladium (Pd) |
| 11 | 6.3 | Pure Thorium (Th) |
| 11 | 6.4 | Wrought iron |
| 10-13 | 5.7-7.0 | Oil-hardening cold work tool steel |
| 7.6-15 | 4.2-8.5 | Pure Scandium (Sc) |
| 11-12 | 6.1-6.8 | Pure Beryllium (Be) |
| 6.3-17 | 3.5-9.4 | Carbide |
| 10-13 | 5.7-7.3 | Nickel chromium molybdenum alloy steel |
| 11-12 | 6.1-6.9 | Shock-resisting tool steel |
| 12 | 6.5 | Structural steel |
| 11-13 | 5.9-7.1 | Air-hardening medium-alloy co [symbol] steel |
| 11-13 | 6.2-7.0 | High-manganese carbon steel |
| 10-14 | 5.6-7.6 | Malleable cast iron |
| 12 | 6.6 | Mold tool steel |
| 8.8-15 | 4.9-8.4 | Nonresulfurized carbon steel |
| 11-14 | 5.9-7.5 | Chromium molybdenum alloy [symbol] |
| 9.4-15 | 5.2-8.2 | Chromium alloy steel |
| 12-13 | 6.5-7.0 | Molybdenum molybdenum sulf [symbol] steel |
| 12 | 6.8 | Chromium vanadium alloy steel |
| 11-14 | 5.9-7.6 | Cold work tool steel |
| 11-14 | 6.0-7.5 | Ductile medium-silicon cast iron |
| 7.6-17 | 4.2-9.4 | Nickel with chromium and or i [symbol] molybdenum |
| 11-14 | 6.2-7.5 | Resulfurized carbon steel |
| 12-13 | 6.4-7.4 | High strength low-alloy steel (H [symbol] |
| 4.8-20 | 2.7-11 | Pure Laretium (Lu) |
| 10-15 | 5.6-8.3 | Duplex stainless steel |
| 9.9-13 | 5.5-7.3 | High strength structural steel |
| 9.0-16 | 5.0-8.9 | Pure Promethium (Pm) |
| 12-13 | 6.5-7.4 | Pure Iron (Fe) |
| 11-14 | 5.9-8.0 | Metal matrix composite alumin [symbol] |
| 10-15 | 5.6-8.6 | Cobalt alloys (including Stellite |
| 6.0-20 | 3.3-11 | Pure Yttrium (Y) |
| 11-15 | 6.0-8.5 | Gray cast iron |
| 9.0-17 | 5.0-9.6 | Precipitation hardening stainless |
| 13 | 7.4 | Pure Bismuth (Bi) |
| 7.0-20 | 3.9-11 | Pure Holmium (Ho) |
| 11-16 | 6.1-8.6 | Nickel copper |
| 13 | 7.4 | Pure Nickel (Ni) |
| 14 | 7.5 | Palladium alloys |
| 12-14 | 6.8-7.7 | Pure Cobalt (Co) |
| 10-17 | 5.6-9.6 | Cast austenitic stainless steel |
| 13-15 | 7.0-8.2 | Gold alloys |
| 8.1-19 | 4.5-11 | High-nickel gray cast iron |
| 14 | 7.8 | Bismuth tin alloys |
| 7.0-20 | 3.9-11 | Pure Uranium (U) |
| 14 | 7.8 | Pure Gold (Au) |
| 10-19 | 5.3-11 | Pure Samarium (Sm) |
| 7.9-21 | 4.4-12 | Pure Erbium (Er) |
| 13-16 | 7.0-9.0 | Nickel chromium silicon gray c [symbol] |
| 14 | 7.8 | Tungsten alloys |
| 14-15 | 7.7-8.4 | Beryllium alloys |
| 12-18 | 6.7-10 | Manganese alloy steel |
| 10-20 | 5.6-11 | Iron alloys |
| 9.7-19 | 5.4-11 | Proprietary alloy steel |
| 15 | 8.5 | White cast iron |
| 12-19 | 6.7-10 | Austenitic cast iron with graphit |
| 8.8-22 | 4.9-12 | Pure Thulium (Tm) |
| 14-18 | 7.5-9.8 | Wrought copper nickel |
| 13-19 | 7.0-10 | Ductile high-nickel cast iron |
| 4.5-27 | 2.5-15 | Pure Lanthanum (La) |
| 16-18 | 8.8-10 | Wrought high copper alloys |
| 17 | 9.4 | Cast high copper alloys |
| 15-19 | 8.3-11 | Wrought bronze |
| 17-18 | 9.2-9.8 | Cast copper |
| 16-18 | 9.1-10 | Wrought copper |
| 17 | 9.6 | Cast copper nickel silver |
| 9.8-25 | 5.4-14 | Austenitic stainless steel |
| 16-19 | 8.9-11 | Cast bronze |
| 16-19 | 8.9-11 | Wrought copper nickel silver |
| 18 | 10 | Pure Barium (Ba) |
| 18 | 10 | Cast copper nickel |
| 18 | 10 | Pure Tellurium (Te) |
| 18-20 | 9.9-11 | Silver alloys |

[symbol]

indicates data missing or illegible when filed

### Nickel-Iron Alloys:

Nickel-iron alloys have been developed mainly for controlled expansion and magnetic applications. The compositions of the principal NILO™ (Invar™ and Kovar™) and NILOMAG™ alloys are given below.

| Alloy | Ni | Fe | Others |
|---|---|---|---|
| NILO alloy 36 | 36.0 | 64.0 | — |
| NILO alloy 42 | 42.0 | 58.0 | — |
| NILO alloy 48 | 48.0 | 52.0 | — |
| NILO alloy K | 29.5 | 53.0 | Co 17.0 |
| NILOMAG alloy 77 | 77.0 | 13.5 | Cu 5.0, Mo 4.2 |

Nickel-Iron materials with trade mark names from Special Metals Corp.

NILO™ alloy K (UNS K94610/W. Nr. 1.3981), otherwise known as Kovar™ which is a nickel-iron-cobalt alloy containing approximately 29% nickel and 17% cobalt and the balance iron. Its thermal expansion characteristics match those of borosilicate glasses and alumina type ceramics. It is manufactured to a close chemistry range, yielding repeatable properties which make it eminently suitable for glass-to-metal seals in mass production applications, or where thermal stability is of paramount importance. The cost of Kovar is approximately $30/lb., whereas Mo is closer to $330/lb.

The physical and mechanical properties of Nilo™ alloy K (Kovar™) are described below:

| Temperature Range | | Total Expansion | Mean Linear Coefficient | |
|---|---|---|---|---|
| ° C. | ° F. | 10⁻³ | 10⁻⁶/° C. | 10⁻⁶/° F. |
| 20-100 | 68-212 | 0.48 | 6.0 | 3.3 |
| 20-150 | 68-302 | 0.75 | 5.8 | 3.2 |
| 20-200 | 68-392 | 0.99 | 5.5 | 3.1 |
| 20-250 | 68-482 | 1.22 | 5.3 | 2.9 |
| 20-300 | 68-572 | 1.43 | 5.1 | 2.8 |
| 20-350 | 68-662 | 1.62 | 4.9 | 2.7 |
| 20-400 | 68-752 | 1.86 | 4.9 | 2.7 |
| 20-450 | 68-842 | 2.28 | 5.3 | 2.9 |
| 20-500 | 68-932 | 2.98 | 6.2 | 3.4 |

Coefficient of Thermal Expansion of Nilo™ alloy K (Kovar™) at temperatures between 20-500° C.

The CTE of Kovar™ is very comparable to pure Mo which has CTE values ranging from 4.9×10⁻⁶/° C. (2.7×10⁻⁶/° F.) to 5.0×10⁻⁶/° C. (2.8×10⁻⁶/° F.). If the substrate crucible is made with an appreciably thick Kovar™ material, it can be engineered to expand at the same rate as the thin film of Mo and not crack. Additionally, the Kovar is 53% iron, 29.5% nickel and 17″ cobalt, which are all elements less expensive than pure Mo, making this a cheaper alternative for the bulk of the crucible. Kovar™ is ductile with excellent room temperature formability characteristics, 42% elongation.

| | | | | Yield Strength | | Elongation | Reduction |
|---|---|---|---|---|---|---|---|
| Temperature | | Tensile Strength | | (0.2% Offset) | | on 50 mm | of |
| ° C. | ° F. | MPa | ksi | MPa | ksi | (2 inch) % | Area % |
| 20 | 68 | 520 | 75.0 | 340 | 49.0 | 42 | 72 |
| 100 | 212 | 430 | 62.0 | 260 | 38.0 | 42 | 72 |
| 200 | 392 | 400 | 58.0 | 210 | 30.0 | 42 | 72 |
| 300 | 572 | 400 | 58.0 | 140 | 20.0 | 45 | 73 |
| 400 | 752 | 400 | 58.0 | 110 | 16.0 | 49 | 76 |

Mechanical properties of Kovar™ exhibiting 42% ductility at room temperature, making it quite formable

Other substrate materials could include pure Tantalum, pure Niobium or one of their alloys.

### Fabrication Processes:

The Kovar™, Ta, Nb, and their alloys are all very cold-formable and can be made by any number of forming process, including but not limited to deep drawing, spinning, hydroforming, bulge forming, flowforming, superplastic forming, roll and welding, fabricating and combinations of these processes. Because of the thin wall and the length-to-diameter ratio of the large crucibles, it would make sense to deep draw a preform and flowform to final wall thickness and length.

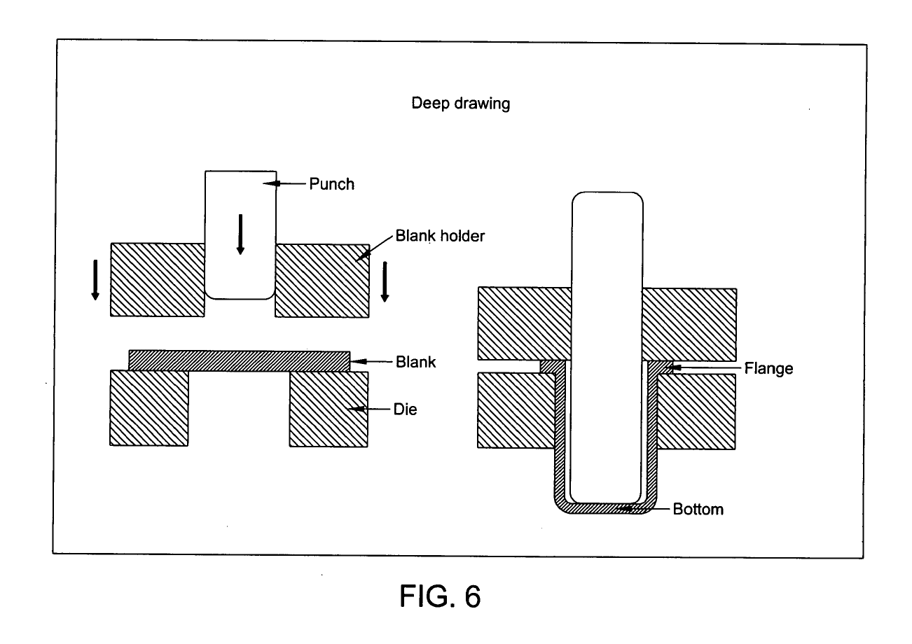

Deep drawing is a sheet metal forming process in which a sheet metal blank is radially drawn into a forming die by the mechanical action of a punch. It is thus a shape transformation process with material retention. The process is considered “deep” drawing when the depth of the drawn part exceeds its diameter. This is achieved by redrawing the part through a series of dies. The flange region (sheet metal in the die shoulder area) experiences a radial drawing stress and a tangential compressive stress due to the material retention property. These compressive stresses (hoop stresses) result in flange wrinkles but wrinkles can be prevented by using a blank holder, the function of which is to facilitate controlled material flow into the die radius. FIG. 6 illustrates a deep draw process, starting from sheet/disc and forming into a bowl with punch and dies.

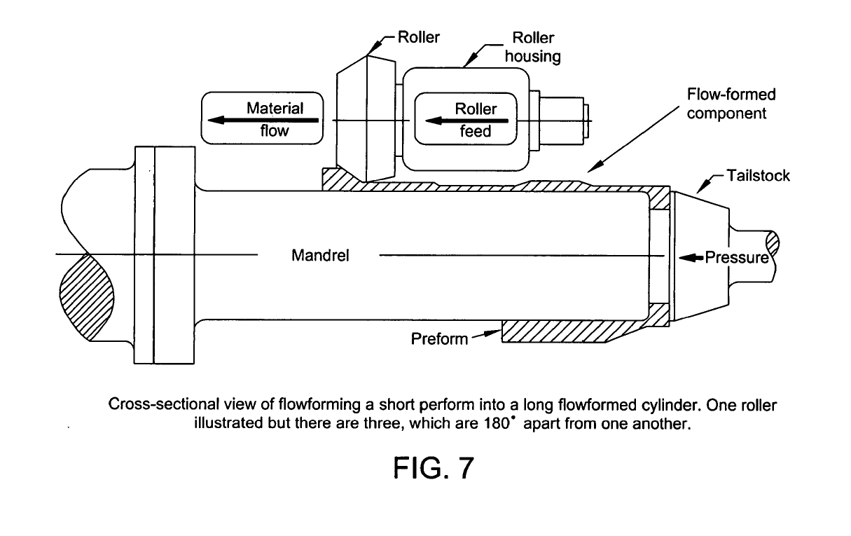

Referring to FIG. 7, flowforming is an advanced, net shape cold metal forming process used to manufacture precise, tubular components that have large length-to-diameter ratios. A cylindrical work piece, referred to as a “preform”, is fitted over a rotating mandrel. Compression is applied by a set of three hydraulically driven, CNC-controlled rollers to the outside diameter of the preform. The desired geometry is achieved when the preform is compressed above its yield strength and plastically deformed and “made to flow”. As the preform's wall thickness is reduced by the set of three rollers, the material is lengthened and formed over the rotating mandrel. The flowforming is done cold. Although adiabatic heat is generated from the plastic deformation, the process is flooded with refrigerated coolant to dissipate the heat. This ensures that the material is always worked well below its recrystallization temperature. With flowforming “cold”, the material's strength and hardness are increased and dimensional accuracies are consistently achieved well beyond accuracies that could ever be realized through hot forming processes.

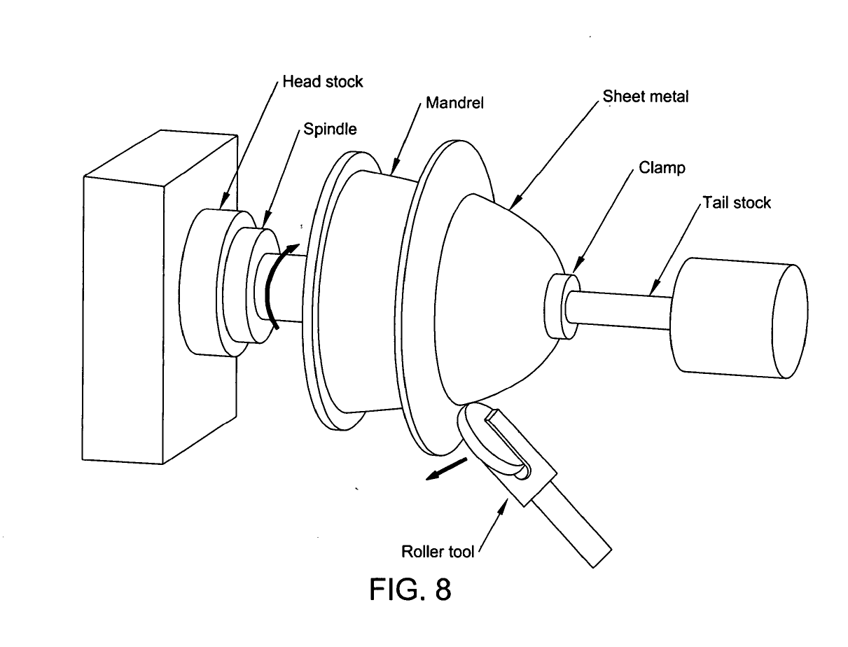

Referring to FIG. 8, in a spinning process, a mandrel, also known as a form, is mounted in the drive section of a lathe. A pre-sized metal disk is then clamped against the mandrel by a pressure pad, which is attached to the tailstock. The mandrel and workpiece are then rotated together at high speeds. A localized force is then applied to the workpiece to cause it to flow over the mandrel. The force is usually applied via various levered tools. Because the final diameter of the workpiece is always less than the starting diameter, the workpiece must thicken, elongated radially, or buckle circumferentially.

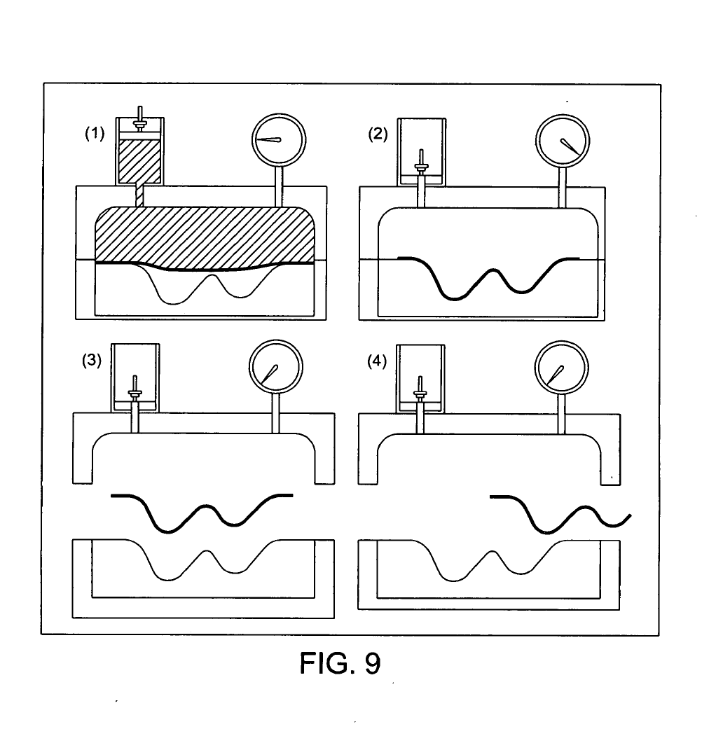

Referring to FIG. 9, hydroforming is a specialized type of die forming that uses a high pressure hydraulic fluid to press room temperature working material into a die. To hydroform aluminum into a vehicle's frame rail, a hollow tube of aluminum is placed inside a negative mold that has the shape of the desired end result. High pressure hydraulic pistons then inject a fluid at very high pressure inside the aluminum which causes it to expand until it matches the mold. The hydroformed aluminum is then removed from the mold.

### Flowforming Molybdenum Crucible:

In another form of the invention, a molybdenum (or molybdenum alloy) preform blank is preheated to a temperature greater than the Ductile Brittle Transition Temperature (DBTT) and flowformed “cold” (e.g., with a coolant) at a temperature below the material's recrystallization temperature. Preheating above DBTT will make the material hot enough to flowform, the adiabatic heat from deformation will keep the material hot while flowforming, and “cold” flowforming (i.e., at a temperature below the recrystallization temperature of the material) will maintain the material's dimensional accuracies. Note that if flowforming is done at a temperature above the recrystallization temperature of the material, neither the dimensional accuracies nor the grain growth can be controlled.

### Some Preferred Forms of the Invention

A crucible made of Mo—Re, Ta and Nb or an alloy thereof, that can be cold-formed to create a crucible with a very fine microstructure to help keep the crucible stable during heating and cooling during single crystal growth. Pure Mo, can be flowformed too if the preform is strategically heated above its ductile brittle transition temperature and below its recrystallization temperature and flowformed warm. The Mo preform only needs to be heated when the flowform rollers contact the preform. Once the plastic deformation of flowform process ensues, the adiabatic heat is sufficient to keep the material above the DBTT.

Using Mo with 5%-20% Re increases the material's ductility and reduces the material's ductile-brittle transition temperature (DBTT) from about 300° C. to about 50° C., making it cold-workable and flowformable at room temperature. The room temp elongation will increase from 8% to 50%.

In certain other embodiments, a material that has a similar coefficient of thermal expansion to Mo, such as Kovar, Ta and/or Nb, is used to allow for a thin film of Mo to be deposited to its substrate. A composite crucible can be made by depositing a Molybdenum film onto the bore (inner diameter) of a backing substrate crucible, i.e. a nickel-iron based metal, that has low/similar coefficient of thermal expansion rates as Mo. The nickel-iron alloys can be formed easily by conventional methods such as spinning, deep drawing and flowforming, none of which can be done easily with pure Mo. The Ni—Fe materials are significantly (an order of magnitude) cheaper than Mo, reducing material costs. The expensive Mo is applied as a coating to the Ni—Fe substrate thru any number of deposition processes, including but not limited to spray forming, sputtering, Chemical Vapor Deposition (CVP) and Physical Vapor Deposition (PVD), wire arc sprayforming, etc. Only a thin film of Mo for barrier (0.005″ to 0.100″ thick) purposes is required for high temperature requirements during the melting of the alumina. The structural integrity/strength of the crucible is achieved from the thicker backing crucible substrate, significantly reducing the material costs. The Mo barrier will shield the substrate from the higher temperatures. Furthermore, the feed stock for plasma spray forming and other deposition process can be powder metal which is Mo's cheapest form compared to mill products (wire, sheet, tube, bar, plate, billet, etc.). A composite/bimetallic crucible with dissimilar metals that have similar coefficient of thermal expansion rates will prove to reduce crucible costs' while improving manufacturability issues.

In other embodiments of the inventions, there can be three materials, one substrate or backing crucible and two layers of vacuum coatings and/or deposited thin films. Also the substrate-backing crucible can be made from other alloys that have low, similar CTE values as Mo, which could include pure Tantalum, pure Zirconium, pure Niobium and their respective alloys. For example, pure Ta has a very high melting temperature and low CTE value, making it an attractive alternative for the substrate. Niobium alloy C103 also has very good combination of high temperature properties and with low CTE values, making it also an attractive alternative for the backing crucible. Producing crucibles for growing single crystal sapphires is just an example. These composite crucibles could be used to grow other crystals such as Aluminum Nitrate, Silicon, Ruby crystals, etc.

In plate form the Ta, Nb, Kovar alloys can be diffused together by diffusion bonding, sintering and hot isotactic pressing (HIP) and by explosively clad bonding. The clad plate can then be cold formed into a formed composite crucible.

Another technique is the use of a pre-treated tantalum or Nb growth crucible. Before use, the tantalum or niobium crucible is annealed at 2200-2500° C. in a carbon-containing atmosphere. During the treatment, the crucible weight gradually increases due to the incorporation of C atoms into tantalum or niobium and the process is continuing until the weight saturates. The resulting weight maximum suggests that no free tantalum remains in the crucible. A three-layer structure of Ta/C—Ta—Ta/C kind is initially formed in the crucible walls during this procedure. As the crucible weight is saturating, the central layer gradually disappears due to the interaction of tantalum with carbon that is probably transported from the vapor via diffusion through small pores in the external T/C layers. The Ta—C helps to keep the material more chemically inert and thermally stable during the single crystal growth process and cooling process. A flowformed structure with very fine grains will allow for a more uniform dispersion of the Carbon during the anneal carbonization process.

### MODIFICATIONS

It should also be understood that many additional changes in the details, materials, steps and arrangements of parts, which have been herein described and illustrated in order to explain the nature of the present invention, may be made by those skilled in the art while still remaining within the principles and scope of the invention.

What is claimed is:

1. A crucible for growing crystals, the crucible including a material selected from tantalum, niobium, a tantalum alloy, and a niobium alloy, wherein the material has an ASTM grain size of 7 to 14.

2. The crucible of claim 1, wherein the material is tantalum.

3. The crucible of claim 1, wherein the material is niobium.

4. The crucible of claim 1, wherein the material is a tantalum alloy.

5. The crucible of claim 1, wherein the material is a niobium alloy.

6. The crucible of claim 1, wherein the material is niobium C-103 alloy.

7. The crucible of claim 1, wherein the material is one of a tantalum alloy and a niobium alloy, and wherein the material further comprises at least one of silicon and thorium.

8. The crucible of claim 1, wherein the material is one of a tantalum alloy and a niobium alloy, and wherein the material further comprises up to 700 ppm silicon.

9. The crucible of claim 1, wherein the material is one of a tantalum alloy and a niobium alloy, and wherein the material further comprises up to 500 ppm thorium.

10. The crucible of claim 1, wherein the crucible is carbonized prior to use.

11. The crucible of claim 10, wherein the crucible is carbonized by annealing the crucible in a carbon-containing atmosphere.

12. The crucible of claim 10, wherein the crucible is carbonized at a temperature of 2200° to 2500° C.

13. The crucible of claim 1, wherein the material has an ASTM grain size of 10 to 14.

14. A method for forming a crucible for growing crystals, the method comprising:
forming a preform blank of a material selected from tantalum, niobium, a tantalum alloy, and a niobium alloy; and
flowforming the preform blank into a crucible at a temperature below the recrystallization temperature of the material.

15. The method of claim 14, wherein the material is tantalum.

16. The method of claim 14, wherein the material is niobium.

17. The method of claim 14, wherein the material is a tantalum alloy.

18. The method of claim 14, wherein the material is a niobium alloy.

19. The method of claim 14, wherein the material is niobium C-103 alloy.

20. The method of claim 14, wherein the material is one of a tantalum alloy and a niobium alloy, and wherein the material further comprises at least one of silicon and thorium.

21. The method of claim 14, wherein the material is one of a tantalum alloy and a niobium alloy, and wherein the material further comprises up to 700 ppm silicon.

22. The method of claim 14, wherein the material is one of a tantalum alloy, and a niobium alloy and further comprises up to 500 ppm thorium.

23. The method of claim 14, further comprising, after flowforming the preform blank, carbonizing the crucible prior to use.

24. The method of claim 23, wherein carbonizing the crucible comprises annealing the crucible in a carbon-containing atmosphere.

25. The method of claim 23, wherein carbonizing the crucible comprises carbonizing the crucible at a temperature of 2200° to 2500° C.

26. The method of claim 14, wherein the material has an ASTM grain size of 7 to 14.

27. The method of claim 14, wherein the material has an ASTM grain size of 10 to 14.

28. A method for growing sapphire crystals, the method comprising:
melting alumina in a crucible, the crucible including a material selected from tantalum, niobium, a tantalum alloy, and a niobium alloy; and
crystallizing the alumina to form sapphire crystals.

29. The method of claim 28, wherein the material is tantalum.

30. The method of claim 28, wherein the material is niobium.

31. The method of claim 28, wherein the material is a tantalum alloy.

32. The method of claim 28, wherein the material is a niobium alloy.

33. The method of claim 28, wherein the material is niobium C-103 alloy.

34. The method of claim 28, wherein the material is one of a tantalum alloy and a niobium alloy, and further comprises least one of silicon and thorium.

35. The method of claim 28, wherein the material is one of a tantalum alloy and a niobium alloy, and further comprises up to 700 ppm silicon.

36. The method of claim 28, wherein the material is one of a tantalum alloy and a niobium alloy, and further comprises up to 500 ppm thorium.

37. The method of claim 28, wherein the crucible is a flowformed crucible.

38. The method of claim 28, wherein the crucible is a carbonized crucible.

39. The method of claim 28, wherein the crucible is a carbonized flowformed crucible.

40. The method of claim 28, wherein the material has an ASTM grain size of 7 to 14.

41. The method of claim 28, wherein the material has an ASTM grain size of 10 to 14.

42. The method of claim 28, wherein the alumina is melted in the crucible at a temperature up to 2300° C.
